(19) United States
(12) Patent Application Publication
(10) Pub. No.: US 2025/0357424 A1
(43) Pub. Date: Nov. 20, 2025

(54) METHOD OF MANUFACTURING ELECTRONIC COMPONENTS WITH WETTABLE FLANKS

(71) Applicant: STMicroelectronics International N.V., Geneva (CH)

(72) Inventors: Gregoire DELACOURT, TOURS (FR); Benjamin JOREZ, CHARENTILLY (FR)

(21) Appl. No.: 19/056,154

(22) Filed: Feb. 18, 2025

(30) Foreign Application Priority Data
May 17, 2024 (FR) FR2405066

(51) Int. Cl. H01L 23/00; H01L 21/56; H01L 21/762; H01L 23/29; H01L 23/31; H05K 1/18

(52) U.S. Cl. CPC H01L 24/94; H01L 21/561; H01L 21/76224; H01L 23/295; H01L 23/3114; H01L 24/29; H01L 24/32; H05K 1/181; H01L 2224/29111; H01L 2224/29139; H01L 2224/29147; H01L 2224/32245; H01L 2224/94; H01L 2924/301

(57) ABSTRACT

The present description provides a method of manufacturing electronic components. The electronic components have wettable flanks. An example method comprises a) providing a substrate having chips formed therein, connection areas being arranged on an upper surface of the substrate, conductive pads being able to cover the connection areas, b) optionally, forming cavities between the chips, c) depositing a layer of insulating material on the substrate and in the cavities, d) making the connection area or conductive pads accessible, e) depositing a layer of conductive material to couple the connection areas of two adjacent chips, f) depositing an additional layer of insulating material, g) thinning the additional layer until the conductive material is accessible, and h) separating the electronic components by dicing through the cavities, provided which the conductive material forms the wettable flanks of the electronic components.

### CROSS REFERENCE TO RELATED APPLICATION(S)

This application claims the priority benefit of French Patent Application Number 2405066, filed on May 17, 2024, entitled “Procédé de fabrication de composants électroniques à flancs mouillables”, which is hereby incorporated by reference to the maximum extent allowable by law.

### TECHNICAL FIELD

The present disclosure concerns the manufacturing of electronic components with wettable flanks. It more particularly aims at the manufacturing of components the to be surface mounted, called “leadless”, that is, with no apparent connections once assembled on the electronic board. These components comprise, on the side of at least one surface, one or a plurality of connection metallizations intended to be soldered to corresponding connection areas of an external device, for example a printed circuit board or another component.

### BACKGROUND

In certain applications, there exists a need for surface-mounted components where connection metallizations intended to be soldered to an external device extends all the way to the flanks of the component. These components are the to have wettable flanks. During the assembly of the component in its environment (for example, on a printed circuit board), the connection metallizations (also called electrical contacts) are welded or soldered to corresponding metal tracks or elements on the side of the printed circuit board. Part of the solder material then adheres to the flanks of the component, which enables a visual inspection of the quality of the connections.

This need, for example, exists in the automotive field or the medical field and, more generally, in fields where it is desired to be sure of the proper assembly of the components, the connections of which are not visible (the connections are under the component) and to guarantee the reliability of the electric connections, once the circuits have been assembled in their environment (flip-chip technology).

### BRIEF SUMMARY

There exists a need to at least partly improve certain aspects of known methods of manufacturing electronic components with wettable flanks.

This object is achieved by a method of manufacturing electronic components with wettable flanks comprising the following steps:
a) providing a substrate having chips formed therein, connection areas of the chips being arranged on an upper surface of the substrate, possibly conductive pads covering the connection areas,
b) optionally, forming cavities or trenches between the chips from the upper surface of the substrate,
c) forming a first layer of insulating material on the substrate, the first layer of insulating material covering the upper surface of the substrate, the first layer of insulating material filling the cavities or the trenches if step b) has been implemented,
d) making accessible connection areas or conductive pads, e) depositing a layer of conductive material to couple the connection areas of two adjacent chips, the layer of conductive material covering the cavities or the trenches if step b) has been implemented,
f) depositing a second layer of insulating material on the conductive material and the upper face of the substrate,
g) thinning the second layer of insulating material until the conductive material is accessible,
h) separating the chips by dicing through the layer of conductive material and through the first layer of insulating material, the cutting being made through the cavities or the trenches if step
b) has been implemented, provided which electronic components with wettable flanks are obtained.

According to an embodiment, during step a), the connection areas are covered with conductive pads and:
step c) is carried out by depositing the first layer of insulating material on the upper surface of the substrate and on the conductive pads,
step d) is carried out by thinning the first layer of insulating material to make the conductive pads accessible, and
during step e), the layer of conductive material is deposited on the conductive pads.

According to an embodiment, step a), the connection areas are not covered with conductive pads and:
step c) is carried out by depositing the first layer of insulating material on the upper surface of the substrate and on the connection areas,
step d) is carried out by etching, and possibly by thinning, the first layer of insulating material, to make the connection areas accessible, and
during step e), the layer of conductive material is deposited on the connection areas.

According to an embodiment, the method comprising, before step g), a step during which a lower surface of the substrate is thinned and is covered with an additional layer of insulating material.

According to an embodiment, the first layer of insulating material and/or the second layer of insulating material and/or the additional layer of insulating material are insulating resin layers, for example epoxy resin layers.

This object is also achieved by an electronic component with wettable flanks comprising a chip formed in a substrate, the chip comprising connection areas arranged on an upper surface of the substrate, a first layer of insulating material covering the flanks of the substrate and the upper surface of the substrate between connection areas, a second layer of insulating material covering the first layer of insulating material on the upper surface of the substrate, a layer of conductive material being arranged on each connection area and further extending, on the one hand, all the way to an upper surface of the electronic component, and, on the other hand, all the way to a flank of the electronic component.

According to an embodiment, an additional layer of insulating material covers a lower surface of the substrate.

According to an embodiment, the first layer of insulating material, the second layer of insulating material, and/or the additional layer of insulating material is an epoxy or phenolic resin layer in which are dispersed electrically-insulating fillers, for example alumina or silica particles.

According to an embodiment, the layer of conductive material is a layer of solderable material, for example a tin-based solderable material, such as SnAgCu.

This object is also achieved by a method of assembly of such an electronic component with an external device, such as a printed circuit board, the method comprising the following steps:
positioning a solder material between the conductive material positioned on the upper surface of the electronic component and connection elements of the external device,
soldering the solder material, provided which the solder material spreads on the connection elements of the external device and on the wettable flanks of the electronic component.

This object is also achieved by the use of such an electronic component with wettable flanks in a motor vehicle, for example in an advanced driver-assistance system, in personal electronics, in communication equipment, such as a computer, a smartphone, a connected object (IoT), or one of their peripherals.

This object is also achieved by a motor vehicle, communication equipment, such as a computer, a smartphone, a connected object (IoT), or one of their peripherals comprising such an electronic component with wettable flanks.

### BRIEF DESCRIPTION OF THE DRAWINGS

The foregoing features and advantages, as well as others, will be described in detail in the rest of the disclosure f specific embodiments given as an illustration and not limitation with reference to the accompanying drawings, in which:

FIG. 1A, FIG. 1B, FIG. 1C, FIG. 1D, FIG. 1E,

FIG. 1F, FIG. 1G, FIG. 1H, and FIG. 1I show cross-section views illustrating steps of a method of manufacturing an electronic component with wettable flanks according to a specific embodiment;

FIG. 2A, FIG. 2B, FIG. 2C, FIG. 2D, FIG. 2E, FIG. 2F, FIG. 2G, FIG. 2H and FIG. 2I show cross-section views illustrating steps of a method of manufacturing an electronic component with wettable flanks according to another specific embodiment;

FIG. 3A and FIG. 3B show cross-section views illustrating steps of a method of assembly of electronic component with wettable flanks with an external device according to a specific embodiment.

FIG. 4 shows a schematic cross-section and profile view of an electronic component with wettable flanks, according to another particular embodiment.

In the various figures, for ease of illustration, the chips may be shown in their entirety or truncated (particularly in the form of half-chips).

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

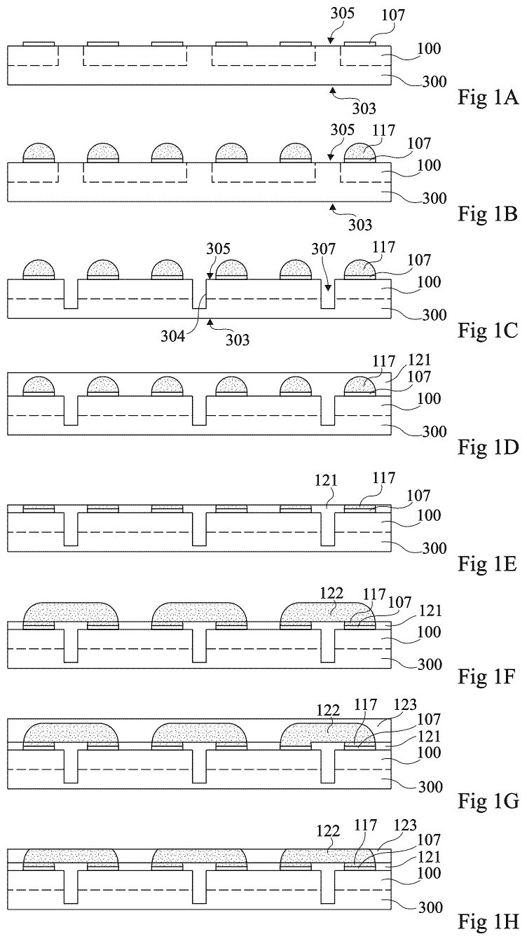

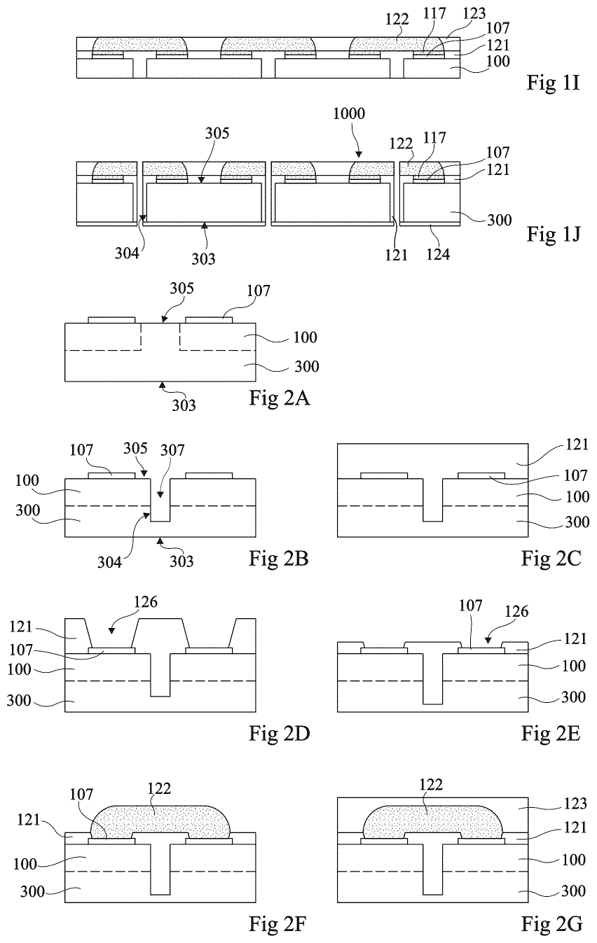

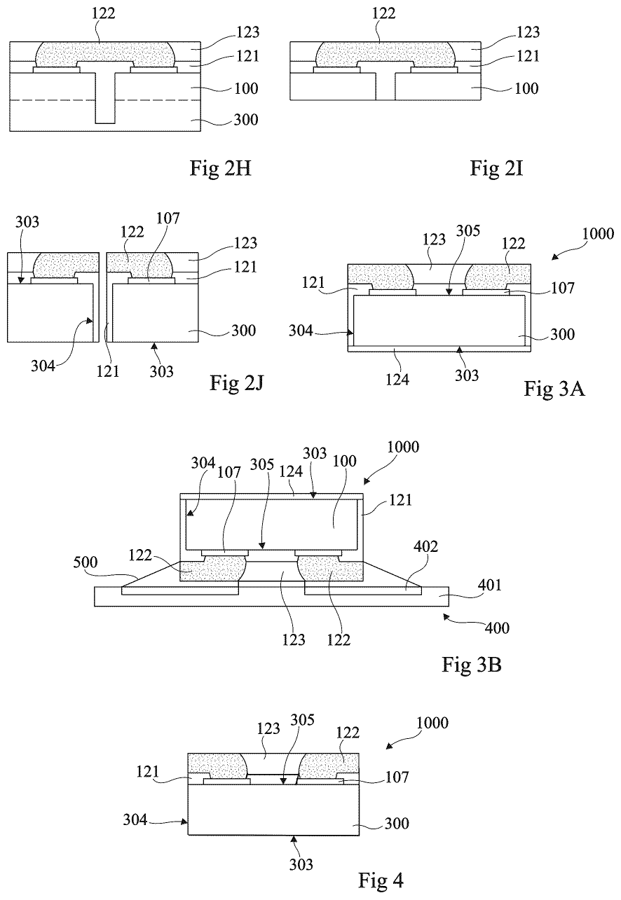

There will now be described in further detail the method of manufacturing an electronic component 1000 with wettable flanks with reference to FIGS. 1A to 1I and 2A to 2I.

The method comprises at least the following steps:
a) providing a substrate 300 having chips 100 formed therein, chips 100 having connection areas 107 arranged on an upper surface 305 of substrate 300 (FIGS. 1A, 2A), possibly conductive pads 117 covering the connection areas 107 (FIG. 1B),
b) forming cavities 307 or trenches between chips 100 (FIGS. 1C, 2B),
c) forming a first layer of insulating material 121 so as to fill cavities 307 or the trenches of insulating material and to cover the upper surface 305 of substrate 300 between connection areas 107 (FIGS. 1D, 2C),
d) making connection pads 107 (FIG. 2D) or conductive pads 117 accessible (FIG. 1E),
e) depositing a layer of conductive material 122 to cover cavities 307 or the trenches, and in particular to cover the insulating material filling cavities 307 or the trenches, and to couple the connection areas 107 of two adjacent chips 100 (FIGS. 1F, 2F),
f) depositing a second layer of insulating material 123 on the conductive material 122 and on the upper surface 305 of the substrate 300 (FIGS. 1G, 2G),
g) thinning the second layer of insulating material 123 until the conductive material 122 is accessible (FIGS. 1H, 2H),
h) separating chips 100 to form electronic components 1000, by cutting through the layer of conductive material 122 and through cavity 307 or the trench, provided which conductive material 122 forms both the electrical connections and the wettable flanks of electronic components 1000 (FIGS. 1I, 2I).

Step b) is an optional step. It may or may not be implemented.

The implementation of step c) prevents any electrical fault (short-circuit, leakage current, etc.) between the connections or other conductive elements connected to these connections and the side of the semiconductor substrate chips.

The layer of conductive material 122 deposited during step d) forms a bridge of conductive material between two adjacent chips. This bridge couples two connection areas 107 of two adjacent chips 100.

When this bridge is cut during step e), the material form a portion of the flanks of electronic components 1000. Components 1000 with wettable flanks are thus obtained.

With such a method, the portion forming the wettable flank has a height which may easily be adapted according to the deposited thickness of conductive material 122. It is possible to have wettable portions with a height of at least 100 μm.

The presence of the first layer of insulating material 121 between conductive material 122 and chip 100 avoids short-circuit risks. Further, the presence of this material in the cavities prevents the collapsing of the conductive material during the cutting. The obtained device has a good mechanical resistance.

The method may further comprise, before step h), a step during which the back side of substrate 300 is thinned and is covered with an additional layer of insulating material 124.

During step c), the first layer of insulating material 121 is, preferably, deposited over the entire upper surface 305 of substrate 300 and then structured. The insulating material fills cavities 307 and covers the upper surface 305 of substrate 300 between connection areas 107.

According to a first alternative embodiment, the substrate 300 provided at step a) comprises conductive pads 117 covering connection areas 107.

According to this first alternative embodiment, for example shown in FIGS. 1A to 1I, the method may comprise at least the following steps:
a) providing substrate 300 having chips 100 formed therein, connection areas 107 being arranged on the upper surface of substrate 300 (FIG. 1A),
covering connection areas 107 with conductive pads 117 (‘wafer bumping’) (FIG. 1B),
b) forming cavities 307 or the trenches between chips 100 (FIG. 1C),
c) filling cavities 307 or the trenches with the first layer of insulating material 121, the first layer of insulating material 121 covering the upper surface of substrate 300 and conductive pads 117 (FIG. 1D),
d) thinning the first layer of insulating material 121 to make a portion of conductive pads 117 accessible (FIG. 1E),
e) depositing the layer of conductive material 122 to cover cavities 307 or the trenches and to couple the connection areas 107 of two adjacent chips 100, the layer of conductive material 122 being in contact with conductive pads 117 (FIG. 1F),
f) depositing a second layer of insulating material 123 on conductive material 122 (FIG. 1G),
g) thinning the second layer of insulating material 132, from the front surface, to make conductive material 122 accessible (FIG. 1H),
h) separating chips 100 by dicing through the layer of conductive material 122 and through cavities 307 or the trenches, provided which conductive material 122 forms the electrical connections and the wettable flanks of electronic components 1000 (FIG. 1I).

According to a second alternative embodiment, during step a), connection areas 107 are not covered with conductive pads.

According to this second alternative embodiment, the method may comprise the following steps:
a) providing substrate 300 having chips 100 formed therein, connection areas 107 being arranged on the upper surface 305 of substrate 300 (FIG. 1A),
b) forming cavities 307 or the trenches between chips 100 (FIG. 2B),
c) filling cavities 307 or the trenches with the first layer of insulating material 121, the first layer of insulating material 121 covering the upper surface of substrate 300 and connection areas 107 (FIG. 2C),
d) making connection areas 107 accessible, for example by laser etching, and possibly by performing a thinning of the front side (FIG. 2E),
e) depositing the layer of conductive material 122 to cover cavities 307 and to couple the connection areas 107 of two adjacent chips 100 (FIG. 2F),
f) depositing a second layer of insulating material 123 on conductive material 122 (FIG. 2G),
g) thinning the second layer of insulating material 123, from the front side, to make conductive material 122 accessible (FIG. 2H),
h) separating chips 100 by cutting through the layer of conductive material 122 and through cavities 307 or the trenches, provided which conductive material 122 forms the electrical connections and the wettable flanks of electronic components 1000 (FIG. 2I).

The different elements and steps of the different variants of the method of manufacturing electronic component 1000 with wettable flanks will now be described in further detail.

The base structure provided at step a) comprises an electronic chip 100 formed from a semiconductor substrate 300, for example made of silicon. It may also be SiC, glass, GaN or sapphire.

Substrate 300 for example has a thickness in the range from 300 to 1200 μm, for example a thickness of approximately 725 μm.

Substrate 300 comprises a first surface 305 (upper surface or front side) and a second surface 303 (back side or lower surface).

Chip 100 is formed on the front side 305 of substrate 300.

Chip 100 may comprise a discrete component or a plurality of discrete components. The discrete component(s) are, for example, selected from among transistors, diodes, filters, etc. Chip 100 may comprise one or a plurality of electronic circuits. Chip 100 enables to implement different electronic functions.

At step a), the manufacturing of the discrete component(s) and/or integrated circuits forming components 1000 is finished. Chips 100 are formed in a same substrate 300, and have not been singulated yet.

One or a plurality of connection areas 107 are formed on the upper surface 305 of substrate 300 to connect chip 100 to external elements/devices 400 (electronic chips or devices).

Electric connection areas 107 are also called “UBM” (for “Under Bump Metallization”) or “bumping pads”. Electric connection areas 107 are made of a conductive material specifically adapted to receiving conductive pads 117, and particularly having a good adherence to conductive pads 117. Electric connection areas 107 comprise at least one of the titanium, following elements: gold, nickel, or copper. Preferably, they comprise gold.

Electric connection areas 107 are, for example, at a distance from 10 to 30 μm from the side wall of the chip. Electric connection areas 107 may be positioned on the upper surface 305 of substrate 300 or be flush with the upper surface 305 of substrate 300 (that is, reach the level of upper surface 305).

During step a), connection areas 107 may have a free upper surface (that is, not be covered, as shown in FIG. 2A) or they may be covered with conductive pads 117 (as shown in FIG. 1B).

Conductive pads 117 may in particular have the shape of a bump. Alternatively, it may be a conductive element having another shape, such as for example a pillar or a cube.

Conductive pads 117 are made of an electrically-conductive and “wettable” material (that is, solderable or weldable), that is, a material on which it is possible to perform a soldering.

Conductive pads 117 are, advantageously, soldered on electric connection areas 107. For example the conductive pads are made of a solderable material based on tin, typically SnAgCu.

At this stage, chip 100 is not protected yet by a package made of an insulating material.

During step b), cavities 307 or trenches (not shown) are formed, in substrate 300, to separate adjacent chips 100. Cavities 307 or trenches delimit the flanks 304 of substrate 300 for each component 1000.

Cavities 307 defining the lateral contours of chips 100 of components 1000 are formed in substrate 300. Cavities 307 extend from the upper surface 305 of substrate 300. According to an example, the depth of cavities 307 corresponds to the desired thickness of the chips of components 100. According to an example, the depth of cavities 307 is in the order of 100 or 300 μm. The depth may be modified according to the desired application. The cavities 307 formed at step b) preferably have a thickness in the range from 50 to 80 μm. The thickness may be modified according to the desired application.

The trenches thoroughly cross the substrate. Trenches define the lateral contours of chips 100. The thickness of the trenches is, for example, in the range from 20 to 80 μm.

Step b) may be carried out by means of a step of partial or total dicing/etching of the substrate. This step may be carried out by means of a dicing or etching device. The dicing device is, for example, a mechanical etching tool such as a saw, or a laser etching tool. The sawing may be performed with one blade or two blades.

According to another embodiment, it may be a laser grooving, or laser dicing, or a plasma dicing. These different dicing methods may also be used in common.

The forming of the space may also be carried out by a step of dicing by introduction of a dislocation by means of a laser (step called ‘stealth dicing’) followed by an expansion step. The so-called ‘stealth dicing’ step consists, with a specific laser, of generating dislocations within the substrate, in the dicing lines. These dislocations are faults present across the substrate thickness which will, under the effect of mechanical stress, enable to separate the chips. It is then sufficient to stretch the adhesive support to space apart the chips and perform the deposition of the material.

In this case, substrate 300 can be brought to final product thickness before the stealth dicing operation.

During step c), cavities 307 or the trenches are filled with a first layer of insulating material 121.

The first layer of insulating material 121 may also cover the upper surface of substrate 300.

For this purpose, a layer 121 of insulating material is deposited in cavities 307, on the first surface 305 of substrate 300. The first layer of insulating material 121 covers connection areas 107 and, possibly, conductive pads 117. These last elements are, at the end of step c), arranged within the insulating material. First layer 121 forms a first portion of the package of components 1000. This first package portion thus protects the upper surface and a part of the flanks of components 1000.

The insulating material may be deposited by means of a press or by vacuum molding.

The insulating material may comprise an electrically-insulating resin. It may be a thermosetting resin or a thermoplastic resin. The material will be selected not to be fusible over the temperature range of use of the electronic components. The resin may be selected from the group comprising: epoxy-type resins, and phenolic-type resins, acrylic-type resins.

The insulating material may also comprise electrically-insulating particles. The particles are, for example, oxide particles, and particularly alumina or silica particles.

The polymerization is, for example, a UV polymerization step or a polymerization by thermal activation.

An anneal may be carried out after step c).

During step d), according to the first alternative embodiment, a portion of the first layer of insulating material 121 is removed to make conductive pads 117 accessible. This step may be carried out by means of a step of front side thinning of insulating material 121.

During step d), according to the second alternative embodiment, a portion of the first layer of insulating material 121 is removed to make connection areas 107 accessible. This step may be carried out by means of a laser etching step and possibly by means of a step of front side thinning of insulating material 121. The two steps (thinning and etching) may be carried out in this order or in the reverse order.

The laser etching results in the forming of openings in the first layer of insulating material 121 in the form of a cone trunk (FIG. 2D).

The front side thinning, implemented at step d), may be carried out by grinding.

During step e), a layer of conductive material 122 is deposited on the layer of insulating material 121. The layer of conductive material 122 is deposited so as to couple the connection areas 107 of two adjacent chips 100. Conductive material 122 forms a bridge (or seam) between chips. The conductive material layer 122 is in contact with the insulating material layer 121. In other words, there is no intermediate element between these two layers.

Conductive material 122 may be in direct contact with the connection areas 107 or coupled to connection areas 107 via conductive pads 117.

Conductive material 122 is, for example, a solderable (or weldable) material. Particularly, it is tin or a tin-based alloy, such as SnAgCu. It may also be a lead alloy or an antimony alloy. It may be SnPb or SnSb.

Conductive material 122 may contain a solder flux.

This material may be deposited by spreading of a paste, for example through a stencil having its openings positioned in front of the connection areas and of the seam to be formed. The stencil is, for example, a stainless steel or nickel sheet provided with openings.

The solderable conductive material may be welded on connection areas 107 or, if applicable, on conductive pads 117.

During step f), a second layer of insulating material 123 is deposited on conductive material 122 and on the front side of chips 100.

The first layer of insulating material 121 and the second layer of insulating material 123 may be made of a same material. For example, it is an insulating resin, such as one of those previously described

A front side thinning step is then carried out to make conductive material 122 accessible (step g)). This material 122 forms, on the front side, the electrical contacts (also called connection metallizations) of the package of components 1000. The electrical front side contacts enable to connect the chip to external elements 400.

The thinning may be carried out to reach the desired height of conductive material.

The front side thinning step may be carried out by grinding.

The method may also comprise a step of thinning of substrate 300 on back side 303. For this purpose, the structure is flipped and attached by its front side 305 to a support. The support is, for example, an adhesive band. The structure is then thinned from its back side 303 so that substrate 300 has its final thickness. According to an example, structure 301 it thinned all the way to the bottom of cavities 307.

The method may advantageously comprise an additional step additionally during which an additional insulating layer 124 is deposited on the back side 303 of the structure to form the rear portion of the package of components 1000. Thus, all the surfaces of substrate 300 are protected. First insulating layer 121 forms the flanks of the package and at least a portion of the front side of the package. Additional layer 124 forms the rear portion of the package. Second insulating layer 123 forms another portion of the front side of the package.

Additional insulating layer 124 is a layer made of an electrically-insulating material. The insulating material of additional layer 124 may be identical to the insulating material of first layer 121 and/or to the insulating material of second layer 123. According to another example, the materials of insulating layers 121, 123, 124 are different. Additional insulating layer 124 is, for example, a resin layer.

During step h), electronic components 1000 are singulated by performing a dicing through conductive material 122 and the first layer of insulating resin 121. The dicing is performed in cavities 307 or in the trenches.

Components 1000 are thus separated from one another.

Conductive material 122 is thus exposed, ensuring the function of wettability of the flanks of electronic components 1000.

Conductive material 122 further allows a direct contacting on the front side of the package, since it is coupled/connected to the electric connection areas 107 of chip 100.

During the previously-described steps, and particularly during the dicing steps, the structure may be positioned on an adhesive. The adhesive used may be an adhesive sensitive to ultraviolet (UV) radiation for dicing applications (‘UV dicing tape’).

FIGS. 1I, 2I, and 3A illustrate, in a partial and simplified cross-section view, an electronic component 1000 with wettable flanks obtained by such a method.

Electronic component 1000 comprises an electronic chip 100, formed in a substrate 300, and a package made of an insulating material protecting chip 100.

The package comprises at least a first layer 121 made of an insulating material covering the flanks of substrate 300 and a portion of the upper surface 305 of substrate 300. It may further comprise a second layer 123 made of an insulating material covering the portion of first layer 121 positioned on the upper surface 305 of substrate 300 and/or an additional layer 124 made of an insulating material covering the back side 303 of substrate 300.

The conductive material forms, on the one hand, the wettable flanks of the package and on the other hand the metallizations on the front side of the package. The conductive material is, for example, embedded in the package. It is coupled or connected either directly to connection areas 107 or to metal pads 117 positioned on connection areas 107. It further extends through first insulating layer 121, and if applicable, through second insulating layer 123, all the way to the upper surface of the package (to enable to connect chip 100 to an external element/device 400) and on the other hand all the way to the flanks of the package to form the wettable flanks of the package.

The layer of conductive material 122 is not directly in contact with substrate 300. The first layer of insulating material 121 is positioned between substrate 300 and layer 122 of conductive material.

The sides of component 1000 are formed successively from insulating material 121 and conductive material 122 (FIGS. 1J, 2J, 3A) when step b) is implemented. When step b) is not implemented, the flanks of component 1000 are formed successively by the flanks of substrate 300, the insulating material 121 and the conductive material 122 (FIG. 4), i.e. the insulating material 121 does not cover the flanks of substrate 300.

Component 1000 is a so-called integrated component.

The obtained components 1000 are surface-mount devices (or SMD) of “flip-chip” type, that is, that they may be attached to an external element/device 400, for example, a printed circuit board, by their upper surface, that is, the surface having the contacts of the package arranged thereon.

Such components 1000 are particularly advantageous to guarantee the reliability of electric connections, once the circuits have been assembled in their environment. They enable to easily view whether the soldering of component 1000 (‘leadless component’) on another device 400 has been performed correctly.

FIGS. 3A and 3B show steps of a method of assembling a component 1000 (‘leadless component’) onto an external device 400, for example a printed circuit board (or PCB) or another component.

External device 400 comprises a substrate 401 covered with tracks 402. Tracks 402 are for example made of copper. In particular, tracks 402 are arranged to protrude from the area having component 1000 attached thereto. In other words, when the assembly is being observed (component 1000 and external device 400, such as a PCB), in top view, tracks 402 are apparent.

A solder material 500 is positioned between component 1000 and the tracks 402 of external device 400 (FIG. 3A). During the soldering, solder material 500 goes up, not only, along the material 122 forming the wettable flanks of components 1000, but also on the tracks 402 of external device 400 (FIG. 3B), which enables to verify whether the soldering has been performed correctly.

The solder joint is visible in top view by automated optical inspection (AOI).

The use of components with wettable flanks also helps to avoid the need for X-ray checks on so-called “double-sided” PCBs, i.e. with components soldered on both sides.

Such electronic components 1000 find applications in many industrial fields, and in particular, in the automotive field, for personal electronics, particularly in the field of communication equipment, computers, and peripherals.

This may, for example, be 5G connection devices or more generally connected devices.

It may also be an advanced driver-assistance system (ADAS).

The electronic chip can be used in a smartphone or for the Internet of things (IoT). The device is, for example, connected by 5G, WIFI, or ultra-wide band (UWB).

The chip may also be advantageous for other fields, such as for example for the industrial field, particularly for green energies.

Such applications are given as an illustration and are not limiting.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing electronic components with wettable flanks comprising:
a) providing a substrate having chips formed therein, connection areas of the chips being arranged on an upper surface of the substrate, possibly conductive pads covering the connection areas,
c) forming a first layer of insulating material on the substrate,
d) making accessible connection areas or conductive pads,
e) depositing a layer of conductive material on the first layer of insulating material, the layer of conductive material being in contact with the first layer of insulating material, to couple the connection areas of two adjacent chips,
f) depositing a second layer of insulating material on the conductive material and an upper face of the substrate,
g) thinning the second layer of insulating material until the conductive material is accessible, and
h) separating the chips by dicing through the layer of conductive material and through the first layer of insulating material, provided which electronic components with wettable flanks are obtained.

2. The method of claim 1, wherein during step a), the connection areas are covered with conductive pads,
wherein step c) is carried out by depositing the first layer of insulating material on the upper surface of the substrate and on the conductive pads,
wherein step d) is carried out by thinning the first layer of insulating material to make the conductive pads accessible, and
wherein during step e), the layer of conductive material is deposited on the conductive pads.

3. The method of claim 1, wherein step c) is carried out by depositing the first layer of insulating material on the upper surface of the substrate and on the connection areas,
wherein step d) is carried out by etching, and possibly by thinning, the first layer of insulating material, to make the connection areas accessible, and
wherein during step e), the layer of conductive material is deposited on the connection areas.

4. The method of claim 1, wherein before step g), a step during which a lower surface of the substrate is thinned and is covered with an additional layer of insulating material.

5. The method of claim 1, wherein the first layer of insulating material or the second layer of insulating material or an additional layer of insulating material are insulating resin layers.

6. The method of claim 5, wherein the insulating resin layers are epoxy resin layers.

7. The method of claim 1, wherein the method comprises a step b), between step a) and step c), during which cavities or trenches are formed between the chips from the upper surface of the substrate, and
wherein during step c), the first layer of insulating material filling the cavities or trenches and covers the upper surface of the substrate.

8. An electronic component with wettable flanks comprising a chip formed in a substrate, the chip comprising connection areas arranged on an upper surface of the substrate, a first layer of insulating material covering the flanks of the substrate and the upper surface of the substrate between connection areas, a second layer of insulating material covering the first layer of insulating material on the upper surface of the substrate, a layer of conductive material being arranged on each connection area and further extending all the way to an upper surface of the electronic component and all the way to a flank of the electronic component, and
wherein the flanks of the electronic component being formed from the first layer of insulating material and the conductive material or from the first layer of insulating material, the conductive material, and the substrate.

9. The electronic component of claim 8, wherein an additional layer of insulating material covers a lower surface of the substrate.

10. The electronic component of claim 8, wherein the first layer of insulating material, the second layer of insulating material, or an additional layer of insulating material is an epoxy or phenolic resin layer in which are dispersed electrically-insulating fillers.

11. The electronic components of claim 10, wherein the electrically-insulating fillers are alumina or silica particles.

12. The electronic component of claim 8, wherein the layer of conductive material is a layer of solderable material, for example a tin-based solderable material.

13. The electronic components of claim 12, wherein the tin-based solderable material is SnAgCu.

14. A method of assembly of an electronic component of claim 7 with an external device, the method comprising:
positioning a solder material between the conductive material positioned on the upper surface of the electronic component and connection elements of the external device, and
soldering the solder material, provided which the solder material spreads on the connection elements of the external device and on the wettable flanks of the electronic component.

15. The method of assembly of claim 14, wherein the external device is a printed circuit board.
